(19) United States
(12) Patent Application Publication
(10) Pub. No.: US 2011/0261540 A1
(43) Pub. Date: Oct. 27, 2011

(54) TOUCH PANEL

(76) Inventor: Jane HSU, Guishan Township (TW)

(21) Appl. No.: 12/963,280

(22) Filed: Dec. 8, 2010

(30) Foreign Application Priority Data
Apr. 21, 2010 (TW) 099207263

(51) Int. Cl. H05K 1/00

(52) U.S. Cl. 361/749; 178/18.03

(57) ABSTRACT

A touch panel has a substrate and a flexible printed circuit board (PCB). The substrate has multiple wires. A first end of each of the wires is formed on a top surface of the substrate, and a second end extends to a bottom surface of the substrate through a side edge of the substrate. The substrate further has an anisotropic conductive layer mounted on the bottom surface of the substrate and covering the second end of each of the wires. The flexible PCB is mounted on a bottom surface of the anisotropic conductive film. Because the flexible PCB is mounted on the bottom surface of the substrate, a drawback of the conventional touch panels that loose bonding occurs at which the flexible PCB is mounted can be resolved.

### BACKGROUND OF THE INVENTION

1. Field of the Invention

The present invention relates to a touch panel, and more particularly to a touch panel having a flexible printed circuit board mounted on a bottom of a substrate of the touch panel with enhanced bonding strength.

2. Description of the Related Art

Touch panels can be classified as capacitive touch panels, resistive touch panels, surface acoustic touch panels, infrared touch panels and the like in terms of the touch panel technologies. Among them, the capacitive touch panels and the resistive touch panels take the leading position in market share. The technologies behind the capacitive touch panels and the resistive touch panels detect the location of a touched point based on capacitive and voltage variation generated at the touched point. Structurally, resistive touch panels are bisubstrate while capacitive touch panels can be either single-substrate or bisubstrate. In case of a single-substrate touch panel, an indium tin oxide (ITO) layer is formed on a top surface of the substrate. In case of a bisubstrate touch panel, two ITO layers are respectively mounted on the surface of the upper substrate and the surface of the lower substrate, which face each other and can be folded together, and serve to sense capacitive or voltage variation. The capacitive or voltage variation signals are outputted to a controller for computation through wires and a flexible PCB mounted on the top surface of the substrate of a single-substrate touch panel or mounted between the two substrates of a bisubstrate touch panel.

As for conventional touch panels, whether single-substrate touch panels or bisubstrate touch panels, the position to which the flexible PCB is mounted is prone to negative impact on the performance of the touch panels. As for the bisubstrate touch panels, since the flexible PCB is mounted and squeezed between the two substrates, the portions between the two substrates where the flexible PCB is mounted are not easy to be tightly bonded. As for the single-substrate touch panels, since a protection layer is additionally mounted on a top surface of the substrate to protect the ITO layer, the issue that the portions between the substrate and the protection layer where the flexible PCB is mounted are not easy to be tightly bonded also exists for a similar reason. To prevent bubbles generated by incorrect bonding from affecting the performance of the touch panels, manufacturers of touch panels develop an improved structure which has drill holes formed through the substrate of the single-substrate touch panels or the lower substrate of the bisubstrate touch panels and corresponding to wires thereon and conductors are mounted through the drill holes. Therefore, signals of the wires can be transmitted to the bottom of the substrate or the lower substrate, and the flexible PCB can be mounted on the bottom of the substrate and the lower substrate to resolve the loose bonding issue.

However, the aforementioned structure is feasible only when applied to a resistive touch panel whose number of the wires is no larger than eight. Since the wires of a capacitive touch panel are plentiful and densely arranged, drill holes must be smaller and positioned more accurately so as to prevent misconnection with adjacent wires. Hence, the drilling process becomes complicated and infeasible and cause significant rise in cost and high defect rate in production.

### SUMMARY OF THE INVENTION

An objective of the present invention is to provide a touch panel having a flexible printed circuit board mounted on a bottom of a substrate of the touch panel with enhanced bonding strength.

To achieve the foregoing objective, the touch panel has a substrate, multiple wires, an anisotropic conductive film and a flexible PCB.

The wires are formed on a top surface of the substrate. Each wire has a first end and a second end, and the second end of the wire extends to a bottom surface of the substrate through a side edge of the substrate. The anisotropic conductive film is mounted on the bottom surface of the substrate and covers the second end of each of the wires. The flexible PCB is mounted on a bottom surface of the anisotropic conductive film.

Preferably, the substrate further has multiple first conductive layers and multiple second conductive layers. The first conductive layers are formed on the top surface of the substrate, and parallelly align in a first direction. Each of the first conductive layers has multiple first sensing units and a first port. The first sensing units are serially connected. The first port is formed on an edge of one of the outermost first sensing units in the first direction. The second conductive layers are formed on the top surface of the substrate, correspond to a portion of the top surface of the substrate unfilled by the first conductive layers, and parallelly align in a second direction that is perpendicular to the first direction. Each of the second conductive layers has multiple second sensing units and a second port. The second sensing units are serially connected. The second port is formed on an edge of one of the outermost second sensing units in the second direction. A count of the wires corresponds to that of the first ports and the second ports respectively on the first conducting layer and the second conducting layer. The first end of each of the wires located on the top surface of the substrate is connected to one of the first ports and the second ports.

The present invention provides an alternative touch panel. The touch panel has a lower substrate, an upper substrate, an anisotropic conductive film and a flexible PCB.

The lower substrate has at least one lower wire formed on a top surface of the lower substrate. Each of the at least one lower wire has a first end and a second end, and the second end of the lower wire extends to a bottom surface of the lower substrate through a side edge of the lower substrate.

The upper substrate is mounted on the top surface of the lower substrate, and has at least one upper wire formed thereon. A first end of each of the at least one upper wires is formed on a bottom surface of the upper substrate, and a second end of the upper wire extends to a bottom surface of the lower substrate through a side edge of the lower substrate.

The anisotropic conductive film is mounted on the bottom surface of the lower substrate, and covers the second end of each of the lower wire and the upper wire.

The flexible PCB is mounted on a bottom surface of the anisotropic conductive film.

The touch panel further has an insulating layer and a separation layer. The insulating layer is frame-shaped, is mounted between the upper substrate and the lower substrate, and covers the first end of each of the lower wires on the top surface of the upper substrate. The separation layer is mounted between the upper substrate and the lower substrate and is surrounded by the insulating layer.

The lower substrate further has a lower conductive layer formed thereon. The first end of each of the at least one lower wire is formed on a top surface of the lower conductive layer.

The upper substrate further has an upper conductive layer formed thereon. The first end of each of the at least one upper wire is formed on a bottom surface of the upper conductive layer and is covered by the insulating layer.

Preferably, the touch panel further comprises an insulating layer mounted between the upper substrate and the lower substrate.

The lower substrate further has multiple lower conductive layers and a lower port. The lower conductive layers parallelly align in a first direction. Each of the lower conductive layers has multiple lower sensing units serially connected. The lower port is formed on an edge of one of the outermost lower sensing units in the first direction.

The upper substrate further has multiple upper conductive layers and an upper port. The upper conductive layers parallelly align in a second direction, and correspond to a portion of a top surface of the lower substrate unfilled by the lower conductive layers. Each of the lower conductive layers has multiple lower sensing units serially connected. The upper port is formed on an edge of one of the outermost upper sensing units in the second direction.

A count of the at least one lower wire formed on the lower substrate corresponds to that of the lower ports. The first end of each of the at least one lower wire is connected to a corresponding lower port.

A count of the at least one upper wire formed on the upper substrate corresponds to that of the upper ports. The first end of each of the at least one upper wire is connected to a corresponding upper port.

Preferably, the touch panel further has an insulating layer mounted between the upper substrate and the lower substrate.

The lower substrate further has multiple lower conducting layers and a lower port. The lower conducting layers are juxtaposedly formed on the top surface of the lower substrate, are rectangular, and align in a first direction. The lower port is formed on one side of a corresponding lower conducting layer that is perpendicular to the first direction.

The upper substrate further has multiple upper conducting layers and an upper port. The upper conducting layers are juxtaposedly formed on the bottom surface of the upper substrate, are rectangular, and align in a second direction that is perpendicular to the first direction. The upper port is formed on one side of a corresponding upper conducting layer that is perpendicular to the second direction.

A count of the at least one lower wire formed on the lower substrate corresponds to that of the lower ports. The first end of each of the at least one lower wire is connected to a corresponding lower port.

A count of the at least one upper wire formed on the upper substrate corresponds to that of the upper ports. The first end of each of the at least one upper wire is connected to a corresponding upper port.

With regards to the touch panel of the present invention, the flexible PCB is mounted on the bottom surface of the substrate, thereby overcoming the shortcoming that the conventional touch panels cannot be tightly bonded at the portion where the flexible PCB is mounted. Besides, one end of each of the wires in the present invention extends to the bottom surface of the substrate through a side edge of the substrate to electrically connect with the flexible PCB through the anisotropic conductive film. In contrast to the conventional drilling process, the present invention can further lower cost and improve yield of touch panels.

Other objectives, advantages and novel features of the invention will become more apparent from the following detailed description when taken in conjunction with the accompanying drawings.

### BRIEF DESCRIPTION OF THE DRAWINGS

FIG. 1 is an exploded perspective view of a single-substrate touch panel in accordance with the present invention;

FIG. 2 is a perspective view of a single-substrate projected capacitive touch panel in accordance with the present invention;

FIG. 3 is a perspective view of a bisubstrate touch panel in accordance with the present invention;

FIG. 4 is an exploded perspective view of a bisubstrate resistive touch panel in accordance with the present invention;

FIG. 5 is an exploded perspective view of a bisubstrate projected capacitive touch panel in accordance with the present invention; and

FIG. 6 is an exploded perspective view of a bisubstrate matrix capacitive touch panel in accordance with the present invention.

### DETAILED DESCRIPTION OF THE INVENTION

Touch panels in accordance with the present invention are characterized in that one end of each of the wires for transmitting signals extends to a bottom surface of a substrate. Such characteristic can be applied to all types of touch panels, such as projected capacitive touch panels built with single substrate, or resistive touch panels, projected capacitive touch panels, matrix capacitive touch panels built with two substrates. Embodiments are listed to describe the touch panels in accordance with the present invention as follows.

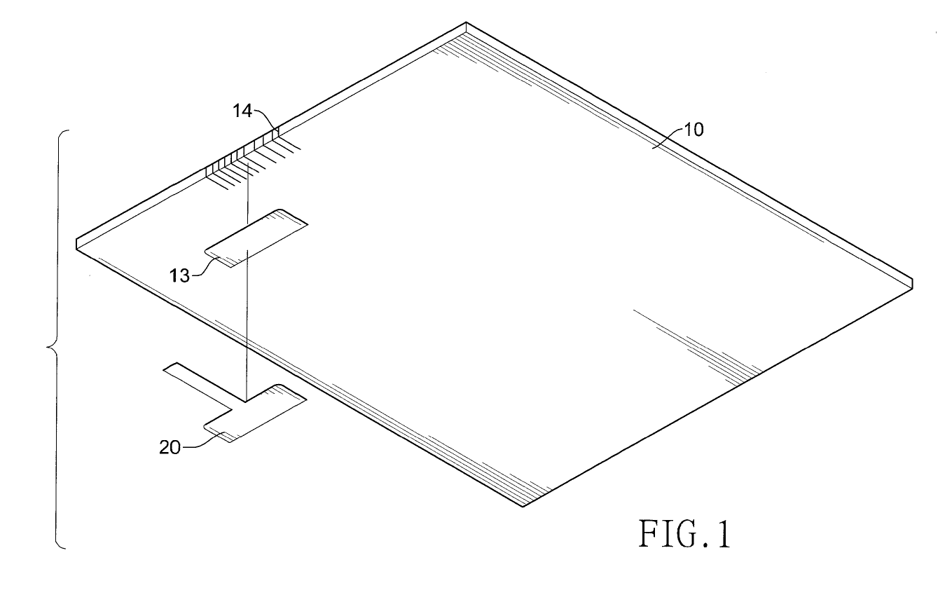

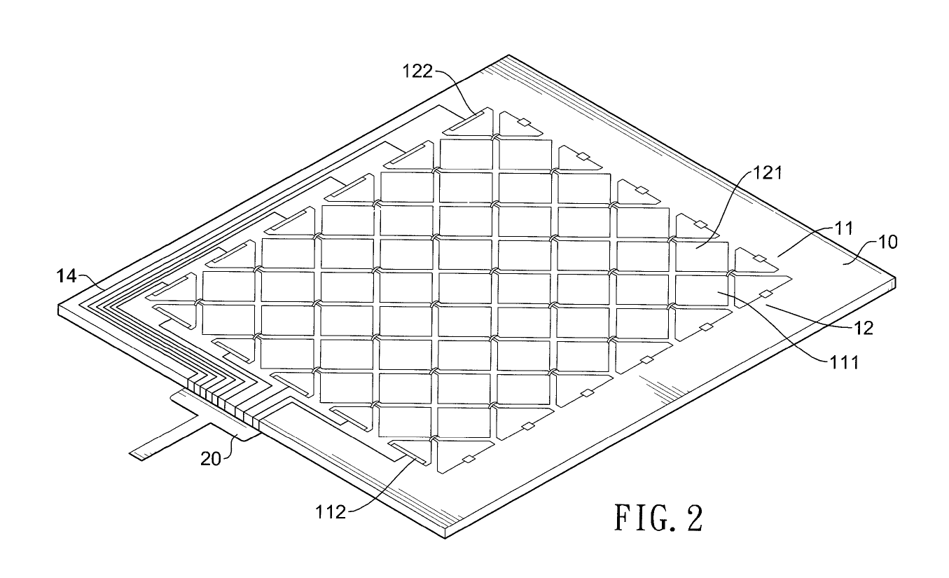

With reference to FIGS. 1 and 2, a single-substrate projected capacitive touch panel in accordance with the present invention has a substrate 10 and a flexible PCB 20.

The substrate 10 has multiple first conductive layers 11, multiple second conductive layers 12, an anisotropic conductive film 13 and multiple wires 14. The first conductive layers 11 and the second conductive layers 12 are formed on a top surface of the substrate 10 and crossly align with each other. The anisotropic conductive film 13 is mounted on a bottom surface of the substrate 10. The wires 14 are formed on the substrate 10. The first conductive layers 11 parallelly align in a first direction and each of the first conductive layers 11 has multiple first sensing units 111 and a first port 112. The first sensing units 111 are serially connected and are composed of ITO. In the present embodiment, the first sensing units 111 are rhombic. Each of the first ports 112 is formed on an edge of one of the outermost first sensing units 111 in the first direction and is made of a conductive material.

The second conductive layers 12 are formed on the top surface of the substrate 10, parallelly align in a second direction that is perpendicular to the first direction, correspond to a portion of the top surface of the substrate 10 unfilled by the first conductive layers 11, and each of the second conductive layers 12 has multiple second sensing units 121 and a second port 122. The second sensing units 121 are serially connected, and are composed of ITO. In the present embodiment, the second sensing units 121 are rhombic. Each of the second ports 122 is formed on an edge of one of the outermost second sensing units 121 in the second direction and is made of a conductive material.

The wires 14 are formed on the top surface of the substrate 10. A count of the wires 14 corresponds to that of the first ports 112 and the second ports 122 respectively on the first conducting layer 11 and the second conducting layer 12. One end of each of the wires 14 on the top surface of the substrate 10 is connected to one of the first ports 142 and the second ports 152. The other end of the wire 14 extends to the bottom surface of the substrate 10 through a side edge of the substrate 10 and is covered by the anisotropic conductive film 13.

The flexible PCB 20 is mounted on a bottom surface of the anisotropic conductive film 13. Each terminal of the flexible PCB 20 is electrically connected with a corresponding wire 14 through the anisotropic conductive film 13.

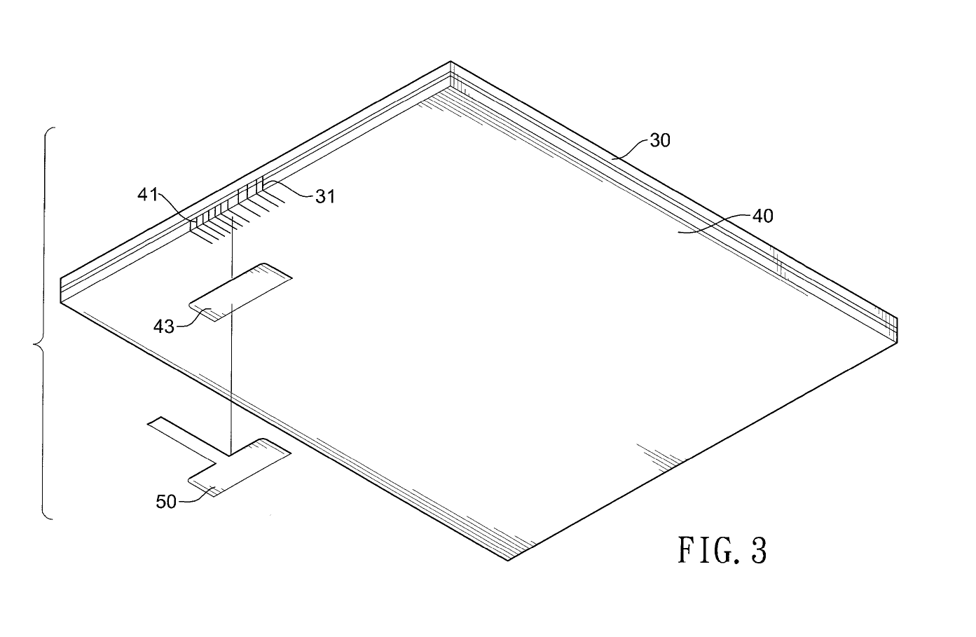

With reference to FIG. 3, a bisubstrate touch panel in accordance with the present invention, whether a resistive touch panel, a projected capacitive touch panels or a matrix capacitive touch panel, has a flexible PCB 50, and an upper substrate 30 and a lower substrate 40 mutually folded together. The upper substrate 30 has at least one upper wire 31 formed thereon, and the lower substrate 40 has at least one lower wire 41 formed thereon. The lower substrate 40 further has an anisotropic conductive film 43 mounted on a bottom surface of the lower substrate 40. The flexible PCB 50 is mounted on a bottom surface of the anisotropic conductive film 43. Specific structures associated with resistive touch panels, projected capacitive touch panels or matrix capacitive touch panels are described in the following.

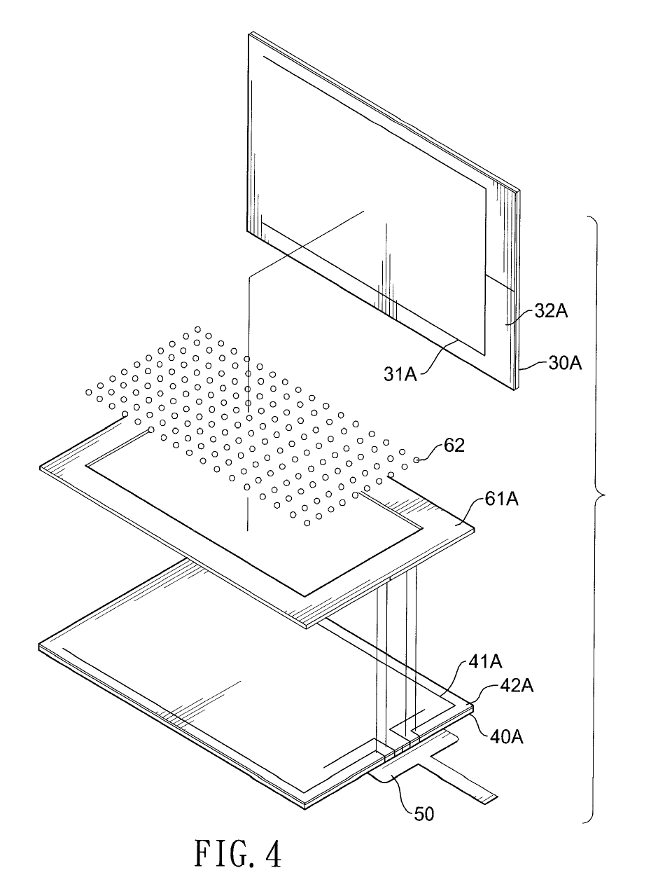

With reference to FIG. 4, a resistive touch panel in accordance with the present invention further has an insulating layer 61A and a separation layer 62. The lower substrate 40A has a lower conductive layer 42A formed on a top surface thereof and is composed of ITO. The lower substrate 40A further has at least one lower wire 41A. Given an example of five-wire resistive touch panel in FIG. 4, four lower wires 41 are formed on a top surface of the lower conductive layer 42. Similar to FIG. 3, each lower wire 41 has two ends, and one end of each of the four lower wires 41 extends to a bottom surface of the lower substrate 40A through a side edge of the lower substrate 40A, is covered by the anisotropic conductive film 43, and is electrically connected with one of terminals of the flexible PCB 50 through the anisotropic conductive film 43.

The insulating layer 61A is frame-shaped and is mounted between the upper substrate 30A and the lower substrate 40A and covers the end of each lower wire 41A on the top surface of the lower substrate 40A.

The separation layer 62 is mounted between the upper substrate 30A and the lower substrate 40A and is surrounded by the insulating layer 61A.

The upper substrate 30A has an upper conductive layer 32A formed on a bottom surface thereof and composed of ITO. The upper substrate 30A further has at least one upper wire 31A. Given the example of five-wire resistive touch panel in FIG. 4 again, one upper wire 31A is formed on the upper conductive layer 32A. The upper wire 31A has two ends, and one end of the upper wire 31A is covered by the insulating layer 61A. Similar to FIG. 3, the other end of the upper wire 31A extends to the bottom surface of the lower substrate 40A through the insulating layer 61A and the side edge of the lower substrate 40A, is covered by the anisotropic conductive film 43, and is electrically connected with a corresponding terminal of the flexible PCB 50 through the anisotropic conductive film 43.

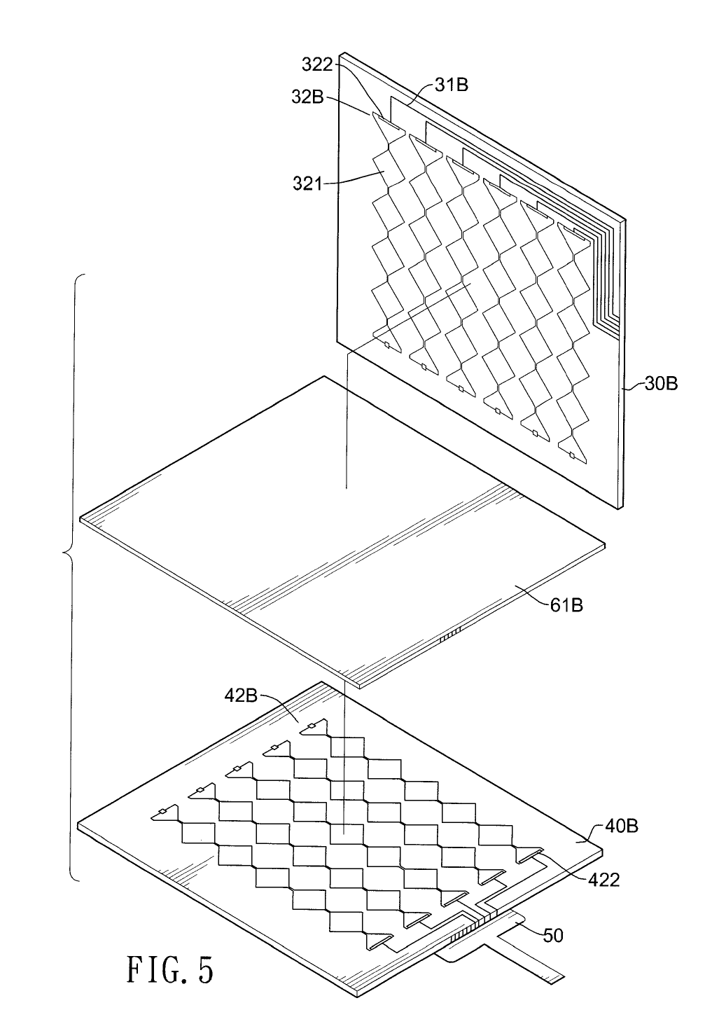

With reference to FIG. 5, a projected capacitive touch panel further has an insulating layer 61B. The lower substrate 40B has multiple lower conductive layers 42B, multiple lower ports 422 and multiple lower wires 41B. The lower conductive layers 42B are formed on a top surface of the lower substrate 40B and parallelly align in a first direction. Each of the lower conductive layers 42B has multiple lower sensing units 421 serially connected and composed of ITO. In the present embodiment, the lower sensing units 421 are rhombic. Each of the lower ports 422 is formed on an edge of one of the outermost lower sensing units 421 in the first direction and is made of a conductive material. A count of the lower wires 41B formed on the lower substrate 40B corresponds to that of the lower ports 422. One end of each of the lower wires 41B is formed on the top surface of the lower substrate 40B and is connected with a corresponding lower port 422. Similar to FIG. 3, the other end of the lower wire 41B extends to a bottom surface of the lower substrate 40B through a side edge of the lower substrate 40B, is covered by the anisotropic conductive film 43, and is electrically connected with a corresponding terminal of the flexible PCB 50 through the anisotropic conductive film 43.

The insulating layer 61B is mounted between the upper substrate 30B and the lower substrate 40B.

The upper substrate 30B has multiple upper conductive layers 32B, multiple upper ports 322 and multiple upper wires 31B. The upper conductive layers 32B are formed on a bottom surface of the upper substrate and parallelly align in a second direction that is perpendicular to the first direction, and correspond to a portion of the top surface of the lower substrate 40B unfilled by the lower conductive layers 42B. Each of the upper conductive layers 32B has multiple upper sensing units 321 serially connected and composed of ITO. In the present embodiment, the upper sensing units 321 are rhombic. Each of the upper ports 322 is formed on an edge of one of the outermost upper sensing units 321 in the second direction and is made of a conductive material. A count of the upper wires 31B formed on the upper substrate 30B corresponds to that of the upper ports 322. One end of each of the upper wires 31B is formed on the bottom surface of the upper substrate 30B and is connected with a corresponding upper port 322. Similar to FIG. 3, the other end of the upper wire 31B extends to the bottom surface of the lower substrate 40B through the insulating layer 61B and a side edge of the lower substrate 40B, is covered by the anisotropic conductive film 43 and is electrically connected with a corresponding terminal of the flexible PCB 50 through the anisotropic conductive film 43.

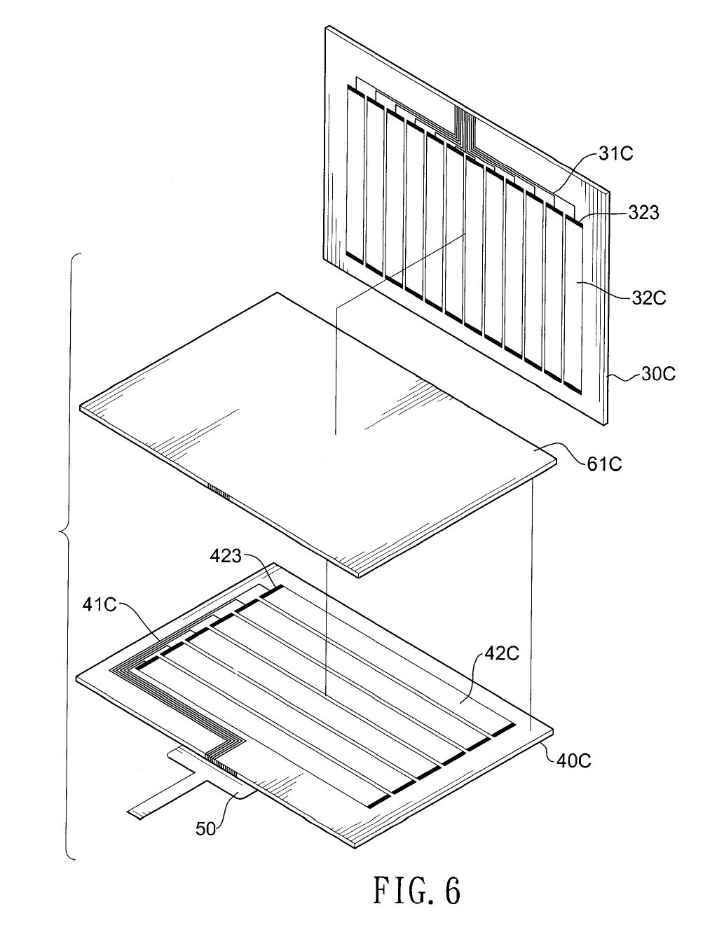

With reference to FIG. 6, a matrix capacitive touch panel further has an insulating layer 61C. The lower substrate 40C has multiple lower conducting layers 42C juxtaposedly formed on a top surface of the lower substrate 40C, are rectangular, align in a first direction, and are composed of ITO. Each of the lower conducting layers 42C has a lower port 423 formed on one side thereof that is perpendicular to the first direction, and is made of a conductive material. The lower wires 41C are formed on the lower substrate 40C, and a count of the lower wires 41C corresponds to that of the lower ports 423. One end of each of the lower wires 41C is formed on the top surface of the lower substrate 40C and is connected to a corresponding lower port 423. Similar to FIG. 3, the other end of the lower wire 41C extends to a bottom surface of the lower substrate 40C through a side edge of the lower substrate 40C, is covered by the anisotropic conductive film 43, and is electrically connected with a corresponding terminal of the flexible PCB 50 through the anisotropic conductive film 43.

The insulating layer 61C is mounted between the upper substrate 30C and the lower substrate 40C.

The upper substrate 30C has multiple upper conducting layers 32C. The upper conducting layers 32C are juxtaposedly formed on a bottom surface of the upper substrate 30C, are rectangular, align in a second direction that is perpendicular to the first direction, and are composed of ITO. Each of the upper conducting layers 32C has a upper port 323 formed on one side thereof that is perpendicular to the second direction, and is composed of a conductive material. The upper wires 31C are formed on the upper substrate 30C, and a count of the upper wires 31C corresponds to that of the upper ports 323. One end of each of the upper wires 31C is formed on the bottom surface of the upper substrate 30C and is connected to a corresponding upper port 323. Similar to FIG. 3, the other end of the upper wire 31C extends to a bottom surface of the lower substrate 40C through the insulating layer 61C and the side edge of the lower substrate 40C, is covered by the anisotropic conductive film 43, and is electrically connected with a corresponding terminal of the flexible PCB 50 through the anisotropic conductive film 43.

In sum, one end of each of the wires of the touch panels in accordance with the present invention, which is connected with the flexible PCB, extends to the bottom surface of the substrate through a side edge of the touch panel so that the flexible PCB can be mounted on the bottom surface of the substrate. Such design resolves the issue that the portion of a conventional touch panel where the flexible PCB is mounted is not easy to be tightly bonded. Also because the fabrication process of the present invention is relatively simpler than the drilling process used in conventional technique, the resulting cost is lowered and the yield is improved.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A touch panel, comprising:
a substrate;
multiple wires formed on a top surface of the substrate, wherein each wire has a first end and a second end, and the second end of the wire extends to a bottom surface of the substrate through a side edge of the substrate;
an anisotropic conductive film mounted on the bottom surface of the substrate, and covering the second end of each of the wires; and
a flexible PCB mounted on a bottom surface of the anisotropic conductive film.

2. The touch panel as claimed in claim 1, wherein the substrate further has:
multiple first conductive layers formed on the top surface of the substrate, and parallelly aligning in a first direction, each of the first conductive layers having:
multiple first sensing units serially connected; and
a first port formed on an edge of one of the outermost first sensing units in the first direction;
multiple second conductive layers formed on the top surface of the substrate, corresponding to a portion of the top surface of the substrate unfilled by the first conductive layers, and parallelly aligning in a second direction that is perpendicular to the first direction, each of the second conductive layers having:
multiple second sensing units serially connected;
a second port formed on an edge of one of the outermost second sensing units in the second direction;
a count of the wires corresponds to that of the first ports and the second ports respectively on the first conducting layer and the second conducting layer, the first end of each of the wires formed on the top surface of the substrate is connected to one of the first ports and the second ports.

3. A touch panel, comprising:
a lower substrate having at least one lower wire formed on a top surface thereon, wherein each lower wire has a first end and a second end, and the second end of the lower wire extends to a bottom surface of the lower substrate through a side edge of the lower substrate;
an upper substrate mounted on the top surface of the lower substrate, and having at least one upper wire formed thereon, wherein each upper wire has a first end and a second end, and the second end of the upper wire extends to a bottom surface of the lower substrate through a side edge of the lower substrate;
an anisotropic conductive film mounted on the bottom surface of the lower substrate, and covered on the second end of each of the lower wire and the upper wire; and
a flexible PCB mounted on a bottom surface of the anisotropic conductive film.

4. The touch panel as claimed in claim 3, wherein
the touch panel further comprises:
an insulating layer being frame-shaped, mounted between the upper substrate and the lower substrate, and covering the first end of each of the lower wires on the top surface of the upper substrate; and
a separation layer mounted between the upper substrate and the lower substrate and surrounded by the insulating layer;
the lower substrate further has a lower conductive layer formed thereon, wherein the at least one lower wire is formed on a top surface of the lower conductive layer, and the first end of each of the at least one lower wire is formed on the top surface of the lower conductive layer; and
the upper substrate further has an upper conductive layer formed thereon, wherein the at least one upper wire is formed on a bottom surface of the upper conductive layer, and the first end of each of the at least one upper wire is covered by the insulating layer.

5. The touch panel as claimed in claim 3, wherein
the touch panel further comprises an insulating layer mounted between the upper substrate and the lower substrate;
the lower substrate further has:
multiple lower conductive layers parallelly aligning in a first direction, each of the lower conductive layers having multiple lower sensing units serially connected;
a lower port formed on an edge of one of the outermost lower sensing units in the first direction;
the upper substrate further has:
multiple upper conductive layers parallelly aligning in a second direction, and corresponding to a portion of a top surface of the lower substrate unfilled by the lower conductive layers, each of the lower conductive layers having multiple lower sensing units serially connected;
an upper port formed on an edge of one of the outermost upper sensing units in the second direction;
a count of the at least one lower wire formed on the lower substrate corresponds to that of the lower ports, and the first end of each of the at least one lower wire is connected to a corresponding lower port; and
a count of the at least one upper wire formed on the upper substrate corresponds to that of the upper ports, and the first end of each of the at least one upper wire is connected to a corresponding upper port.

6. The touch panel as claimed in claim 3, wherein
the touch panel further comprises an insulating layer mounted between the upper substrate and the lower substrate;
the lower substrate further has:
multiple lower conducting layers juxtaposedly formed on the top surface of the lower substrate, being rectangular, and aligning in a first direction; and
a lower port formed on one side of a corresponding lower conducting layer that is perpendicular to the first direction;
the upper substrate further has:
multiple upper conducting layers juxtaposedly formed on the bottom surface of the upper substrate, being rectangular, and aligning in a second direction that is perpendicular to the first direction; and
an upper port formed on one side of a corresponding upper conducting layer that is perpendicular to the second direction;
a count of the at least one lower wire formed on the lower substrate corresponds to that of the lower ports, and the first end of each of the at least one lower wire is connected to a corresponding lower port; and
a count of the at least one upper wire formed on the upper substrate corresponds to that of the upper ports, and the first end of each of the at least one upper wire is connected to a corresponding upper port.
